(19) United States
(12) Patent Application Publication
(10) Pub. No.: US 2020/0412086 A1
(43) Pub. Date: Dec. 31, 2020

(54) VERTICAL CAVITY SURFACE-EMITTING LASER, MANUFACTURING METHOD THEREOF, MANUFACTURING METHOD OF MODULE AND METHOD OF PICKING UP VERTICAL CAVITY SURFACE-EMITTING LASER

(71) Applicant: SUMITOMO ELECTRIC INDUSTRIES, LTD., Osaka (JP)

(72) Inventor: Yukihiro TSUJI, Osaka-shi (JP)

(73) Assignee: SUMITOMO ELECTRIC INDUSTRIES, LTD., Osaka (JP)

(21) Appl. No.: 16/889,052

(22) Filed: Jun. 1, 2020

(30) Foreign Application Priority Data
Jun. 28, 2019 (JP) 2019-121455

(51) Int. Cl. H01S 5/042; H01S 5/022; H01S 5/183; H01S 5/343

(52) U.S. Cl. CPC H01S 5/0422; H01S 5/02268; H01S 5/02284; H01S 5/02252; H01S 5/18347; H01S 5/02276; H01S 5/18313; H01S 5/18327; H01S 5/18361; H01S 5/3432; H01S 5/1835

(57) ABSTRACT

A vertical cavity surface-emitting laser includes a light emitting portion provided on a substrate, a first pad provided on the substrate, the first pad being electrically connected to the light emitting portion, and a second pad provided on the substrate, the second pad being electrically isolated from the light emitting portion and the first pad.

### CROSS-REFERENCE TO RELATED APPLICATION

This application is based upon and claims the benefit of priority of the prior Japanese Patent Application No. 2019-121455, filed on Jun. 28, 2019, the entire contents of which are incorporated herein by reference.

### FIELD

The present invention relates to a surface emitting laser, a method of manufacturing the same, a manufacturing method of a module and a method of picking up a vertical cavity surface-emitting laser.

### BACKGROUND

International Publication No. WO 2015/033649 (Patent Document 1) discloses a vertically cavity surface-emitting laser (VCSEL).

### SUMMARY

A vertically cavity surface-emitting laser (VCSEL) is picked up and mounted on a circuit board. At this time, a pad of the VCSEL is recognized as an image, and an alignment or the like is performed by using the pad as a positional standard for alignment. Incidentally, the pad may has a trace of a probe on its surface. Because a needle-shape probe is brought into contact with the pad when the VCSEL is in an inspection of its electrical characteristics, and a trace of the probe remains on the pad. The trace of the probe makes it difficult to recognize the image of the pad, and also makes it difficult to use the pad as the positional standard for alignment. It is therefore an object of the present invention to provide a VCSEL capable of recognizing an image of a pad, a method of manufacturing the same, a method of manufacturing a module and a method of picking up a vertical cavity surface-emitting laser.

A vertical cavity surface-emitting laser according to the present disclosure includes a light emitting portion provided on a substrate, a first pad provided over the substrate, the first pad being electrically connected to the light emitting portion, and a second pad provided over the substrate, the second pad being electrically isolated from the light emitting portion and the first pad.

A method of manufacturing a vertical cavity surface-emitting laser according to the present disclosure includes a step of forming a light emitting portion on a substrate, a step of forming a first pad electrically connected to the light emitting portion on the substrate, and a step of forming a second pad electrically isolated to the light emitting portion and the first pad on the substrate.

A method of manufacturing a module according to the present disclosure includes steps of: preparing a vertical cavity surface-emitting laser having a light emitting portion provided on a substrate, a first pad provided on the substrate, and a second pad provided on the substrate, the first pad being electrically connected to the light emitting portion, the second pad being electrically isolated from the light emitting portion and the first pad; detecting a position of the vertical cavity surface-emitting laser by capturing an image of the second pad; mounting the vertical cavity surface-emitting laser on another substrate by using the position detected in the detecting.

A method of picking up a vertical cavity surface-emitting laser according to the present disclosure includes steps of: storing an image of a first vertical cavity surface-emitting laser having a light emitting portion provided on a substrate, a first pad provided on the substrate, and a second pad provided on the substrate, the first pad being electrically connected to the light emitting portion, the second pad being electrically isolated from the light emitting portion and the first pad; capturing an image of a second vertical cavity surface-emitting laser having a light emitting portion provided on a substrate, a first pad provided on the substrate, and a second pad provided on the substrate, the first pad being electrically connected to the light emitting portion, the second pad being electrically isolated from the light emitting portion and the first pad; determining whether to pick up the second vertical cavity surface-emitting laser, based on a collation results between the second pad in the image of the first vertical cavity surface-emitting laser and the second pad in the image of the second vertical cavity surface-emitting laser.

### BRIEF DESCRIPTION OF THE DRAWINGS

FIG. 1A is a plan view illustrating a vertical cavity surface-emitting laser according to Example 1.

FIG. 1B is a cross-sectional view illustrating a vertical cavity surface-emitting lasers.

FIG. 2A is an enlarged cross-sectional view of a vicinity of pads.

FIG. 2B is a flowchart illustrating from a manufacturing of a vertical cavity surface-emitting laser to an alignment of an optical fiber to the vertical cavity surface-emitting laser.

FIG. 3A and FIG. 3B are plan views illustrating methods of manufacturing a vertical cavity surface-emitting laser.

FIG. 4A and FIG. 4B are plan views illustrating methods of manufacturing a vertical cavity surface-emitting laser.

FIG. 5A and FIG. 5B are plan views illustrating methods of manufacturing a vertical cavity surface-emitting laser.

FIG. 6A and FIG. 6B are plan views illustrating methods of manufacturing a vertical cavity surface-emitting laser.

FIG. 7A and FIG. 7B are plan views illustrating methods of manufacturing a vertical cavity surface-emitting laser.

FIG. 8A and FIG. 8B are cross-sectional views showing methods of manufacturing pads.

FIG. 9A and FIG. 9B are cross-sectional views showing methods of manufacturing pads.

FIG. 10A and FIG. 10B are cross-sectional views showing methods of manufacturing pads.

FIG. 11A is a block diagram illustrating an image recognition apparatus.

FIG. 11B is a flowchart illustrating a process executed by the image recognition apparatus.

FIG. 12A and FIG. 12B are diagrams illustrating images of a vertical cavity surface-emitting laser.

FIG. 13A is a cross-sectional view illustrating a method of mounting a vertical cavity surface-emitting laser on a board.

FIG. 13B is a cross-sectional view illustrating alignment of an optical fiber.

### DESCRIPTION OF EMBODIMENTS

First, the contents of the embodiment of the present disclosure will be described by enumerating.

An embodiment of the present disclosure is (1) a vertical cavity surface-emitting laser including a light emitting portion provided on a substrate, a first pad provided over the substrate, the first pad being electrically connected to the light emitting portion, and a second pad provided over the substrate, the second pad being electrically isolated from the light emitting portion and the first pad. In a binarized image processed in an image recognition, the second pad becomes a white portion. The second pad is not used in a test for electric properties, and has no traces on its surface. Thus it is possible to use the second pad as an image for standard.

(2) The second pad may have a shape which is similar to that of the first pad, and may have a size which is different from that of the first pad. Since the first pad and the second pad have difference in size, the first pad and the second pad can be distinguished from each other. An image of the first pad is not mistaken for the image the second pad in the image recognition.

(3) The first pad and the second pad may have circular shapes. The second pad may have a size different from that of the first pad. Since the first pad and the second pad can be distinguished from each other by their difference in size, the second pad can be used as a standard for an image recognition. For example, a circular second pad is easier to recognize than a polygon.

(4) The first pad may have a diameter of 60 μm or more, and the second pad may have a diameter of 40 μm or more and less than 60 μm. Since the circularity of the second pad is increased proportional to the size, it is possible to recognize the image of the second pad more accurately.

(5) The surface emitting vertical-cavity laser may have an insulating film covering the second pad, and the insulating film may have a first opening through which the first pad is exposed. In a test for electrical properties, since the first pad is exposed from the insulating film, a probe can electrically contact with the first pads inside the opening.

(6) The first pad and the second pad may be formed of gold. In the binarized image, since the second pad becomes a white portion, it is possible to recognize the second pad as an image.

(7) A method of manufacturing a vertical cavity surface-emitting laser includes steps of: forming a light emitting portion on a substrate, forming a first pad on the substrate, the first pad being electrically connected to the light emitting portion, and forming a second pad on the substrate, the second pad being electrically isolated from the light emitting portion and the first pad. In the binarized image, since the second pad becomes a white portion, it is possible to recognize the second pad as an image.

(8) A method of manufacturing a module includes steps of: preparing a vertical cavity surface-emitting laser having a light emitting portion provided on a substrate, a first pad provided on the substrate, and a second pad provided on the substrate, the first pad being electrically connected to the light emitting portion, the second pad being electrically isolated from the light emitting portion and the first pad; detecting a position of the vertical cavity surface-emitting laser by capturing an image of the second pad; mounting the vertical cavity surface-emitting laser on another substrate by using the position detected in the detecting.

(9) The method may further include positionally aligning an optical fiber with respect to the vertical cavity surface-emitting laser by using the position detected in the detecting.

(10) A method of picking up a vertical cavity surface-emitting laser includes steps of: storing an image of a first vertical cavity surface-emitting laser having a light emitting portion provided on a substrate, a first pad provided on the substrate, and a second pad provided on the substrate, the first pad being electrically connected to the light emitting portion, the second pad being electrically isolated from the light emitting portion and the first pad; capturing an image of a second vertical cavity surface-emitting laser having a light emitting portion provided on a substrate, a first pad provided on the substrate, and a second pad provided on the substrate, the first pad being electrically connected to the light emitting portion, the second pad being electrically isolated from the light emitting portion and the first pad; determining whether to pick up the second vertical cavity surface-emitting laser, based on a collation results between the second pad in the image of the first vertical cavity surface-emitting laser and the second pad in the image of the second vertical cavity surface-emitting laser.

(11) The first image and the second image may be binarized images.

Specific examples of a vertical cavity surface-emitting laser and a manufacturing method thereof according to an embodiment of the present disclosure will be described below with reference to the drawings. It should be noted that the present disclosure is not limited to these examples, but is indicated by the claims, and it is intended to include all modifications within the meaning and range equivalent to the claims.

### First Embodiment

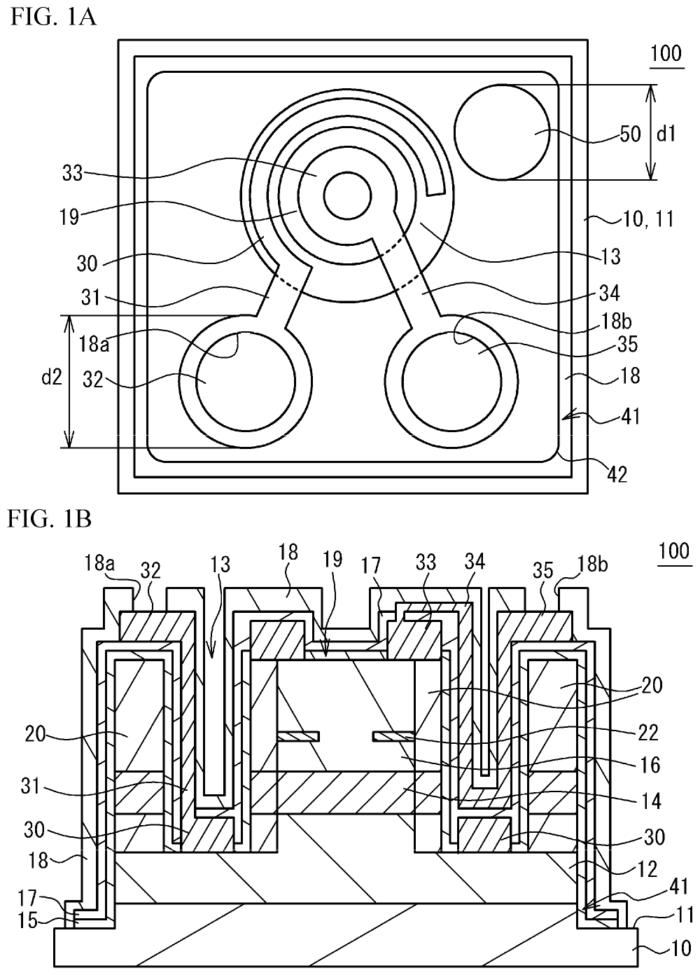

(Surface emitting laser) FIG. 1A is a plan view illustrating a surface emitting laser (vertical cavity surface emitting-laser: VCSEL) 100 according to the first embodiment, and FIG. 1B is a cross-sectional view illustrating the surface emitting laser 100. In FIG. 1A, insulating films such as an insulating film 18 are seen through.

As illustrated in FIG. 1A, the surface emitting laser 100 has a rectangular shape with a side of 200 μm to 300 μm, for example. A trench 11 for element isolation is provided in an outer peripheral portion of the surface emitting laser 100, and a substrate 10 is exposed in the trench 11. Semiconductor layers such as a lower reflector layer 12, an active layer 14, and an upper reflector layer 16, which will be described later, are located on the substrate 10 to form a mesa 41. The mesa 41 is formed to provide the trench 11 for separation of the surface emitting laser 100. The mesa 41 is surrounded by the trench 11, is rectangular, and has a chamfer 42 at each apex. A mesa 19, a pad 32 (first pad), a pad 35 (first pad), and a pad 50 (second pad) are located inside the mesa 41 and are surrounded by the trench 11. The mesa 19 includes a light emitting portion of the surface emitting laser 100. A groove 13 is provided around the mesa 19. An electrode 33 is provided on the mesa 19, and the electrode 33 is electrically connected to the pad 35 by a wiring 34. An electrode 30 is provided in the groove 13, and the electrode 30 is electrically connected to the pad 32 by a wiring 31. The pads 32 and 35 are bonding pads used for an electrical connection between the surface emitting laser 100 and an external electric source. On the other hand, the pad 50 is a dummy pad which is not electrically connected to the electrodes 30 and 33. In other words, the pad 50 is electrically isolated from the light emitting portion of the mesa 19, and the pads 32 and 35. The pad 50 is an object of an image recognition, and functions as a mark for alignment.

As illustrated in FIG. 1B, the surface emitting laser 100 includes the substrate 10, the lower reflector layer 12, the active layer 14, and the upper reflector layer 16. The lower and upper reflector layers 12, 16 are DBRs (Distributed Bragg Reflectors).

The substrate 10 is, for example, a semi-insulating gallium arsenide (GaAs) semiconductor substrate. The lower reflector layer 12, the active layer 14, and the upper reflector layer 16 are sequentially stacked on the substrate 10, and these semiconductor layers form the mesa 19.

The lower reflector layer 12 is, for example, a semiconductor-multilayered film in which n-type aluminum gallium arsenide (AlₓGa₁₋ₓAs, 0≤x≤0.3 and Al_{y}Ga_{1-y}As, 0.7≤y≤1) having different compositions are alternately laminated with an optical film thickness λ/4.λ is a wavelength of light emitted from the active layer 14. The lower reflector layer 12 is doped with, for example, silicon (Si). The lower reflector layer 12 includes a conductive contact layer in contact with the electrodes 30, and the contact layer is formed of, for example, AlGaAs.

The active layer 14 is formed of, for example, GaAs and indium gallium arsenide (InGaAs), and has a multiple quantum well (MQW) structure in which quantum well layers and barrier layers are alternately stacked. The active layer 14 has an optical gain. A cladding layer (not illustrated) may be interposed between the active layer 14 and the lower reflector layer 12, and between the active layer 14 and the upper reflector layer 16.

The upper reflector layer 16 is, for example, a semiconductor-multilayered film in which p-type AlₓGa₁₋ₓAs(0≤x≤0.3) and Al_{y}Ga_{1-y}As (0.7≤y≤1) are alternately laminated with an optical film thickness λ/4. The upper reflector layer 16 is doped with carbon (C), for example. The upper reflector layer 16 includes a conductive contact layer in contact with the electrodes 33, and the contact layer is formed of, for example, AlGaAs or GaAs.

The substrate 10, the lower reflector layer 12, the active layer 14, and the upper reflector layer 16 may be formed of other compound semiconductors. For example, the substrates 10 in addition to GaAs, may be such as AlₓGa₁₋ₓAs(0≤x≤0.2), which includes Ga and As.

A current confinement layer 22 is formed by selectively oxidizing a part of the upper reflector layer 16. The current confinement layer 22 is formed by oxidizing the periphery of the upper reflector layer 16, and the center of the upper reflector layer 16 is not oxidized. The current confinement layer 22 includes, for example, aluminum oxide (Al₂O₃) which is insulating in the periphery. Less current flows in the oxidized portion than in the portion that is not oxidized. Therefore, an unoxidized portion on the center of the upper reflector layer 16 becomes a current path, and efficient current injection to the active layer 14 becomes possible.

A high-resistance region 20 is formed on the outer side of the current confinement layer 22 and on the periphery portion of the mesa 19. The high-resistance region 20 is formed by implanting ions such as protons, for example. The groove 13 extends through the high-resistance region 20 in the thickness direction, reaches the lower reflector layer 12, and surrounds the mesa 19. The trench 11 is located outside the groove 13 and the high-resistance region 20, surrounds them, and reaches the substrate 10 in the thickness direction. A stack of the semiconductor layers forms the mesa 41 inside the trench 11.

An insulating film 15 (first insulating film) is formed of, for example, silicon oxynitride (SiON) or silicon oxide (SiO₂) having a thickness of 400 nm, and covers a surface of the high-resistance regions 20 and a surface of the mesas 19. An insulating film 17 (second insulating film) is formed of an insulator such as silicon nitride (SiN) having a thickness of 100 nm and a refractive index of 2.0, for example, and covers the insulating film 15. In order to reduce a parasitic capacitance, the dielectric constants of the insulating films 15 and 17 are preferably low. The insulating films 15 and 17 function as a part of reflective films for reflecting light emitted from the active layer 14, and the thicknesses and refractive indices are determined so as to increase the reflectance. The insulating film 18 (second insulating film) is formed of, for example, SiN having a thickness of 100 nm and a refractive index of 2.0, and covers the insulating film 17. The insulating film 18 has an opening 18a through which the pad 32 is exposed and an opening 18b through which the pad 35 is exposed.

The electrode 30 is for an negative-side electrode having a laminated structure of gold (Au), germanium (Ge), and nickel (Ni), and is provided inside the groove 13 and on the contact layer in the lower reflector layer 12. The electrode 33 is for a positive-side electrode having a stacked structure of titanium (Ti), platinum (Pt), and Au, and is provided on the mesa 19 and on the surface of the contact layer in the upper reflector layer 16. The electrodes 30 and 33 are ohmic electrodes. The pads 32 and 35 are located outside the mesa 19 and above the high resistance region 20. The wiring 31 and the pad 32 are electrically connected to the electrode 30, and the electrode 30 is electrically connected to the lower reflector layer 12 through an opening of the insulating film 17. The wiring 34 and the pad 35 are electrically connected to the electrode 33, and the electrode 33 is electrically connected to the upper reflector layer 16. The wirings 31, 34 and the pads 32, 35 are made of Au. The wirings and pads are provided with seed metals underneath, not illustrated in FIG. 1A and FIG. 1B.

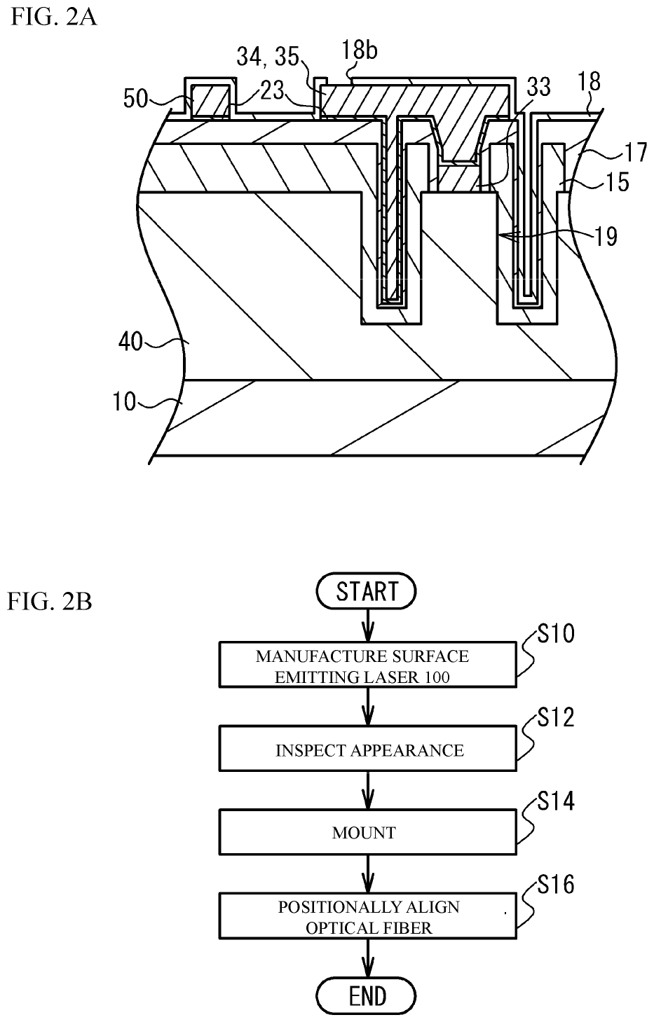

FIG. 2A is an enlarged cross-sectional view of the vicinity of the pad 50, and a scale is changed from that in FIG. 1B. A semiconductor layer 40 illustrated in FIG. 2A is a stack of semiconductor layers of the lower reflector layer 12, the active layer 14, the upper reflector layer 16, and the semiconductor layer 40 includes the high resistance region 20. The pad 50 is located outside the mesa 19 and outside the groove 13. The pad 50 is provided over the substrate 10 and over the semiconductor layer 40, specifically over the high resistance region 20. A seed metal 23 is provided on a surface of the insulating film 17. The insulating film 17 is provided on the semiconductor layer 40. The wiring 34, the pad 32, and the pad 50 are provided on the seed metal 23. The pad 50 is covered with the insulating film 18. A surface of the pad 50 is not exposed from the insulating film 18. The seed metal 23 is formed of a metal such as Ti and Au. The pad 50 is formed of the same material as the pad 32 such as an Au plating layer.

As illustrated in FIG. 1A, the pad 50 has a circular shape, and a diameters dl of the pad 50 is, for example, 40 μm. The pads 32 and 35 have circular shapes, and diameters d2 of the pads 32 and 35 are, for example, 65 μm. That is, the shape of the pad 50 is similar to the shapes of the pads 32 and 35, and the pad 50 is smaller than the pads 32 and 35. The circularity of the pad 50 is, for example, 1±0.06. A positional separation between the pad 50 and the mesa 19 is, for example, 65 μm. The pad 50 may have a shape other than a circle, such as an ellipse or a polygon. The number of the pads 50 may be one or two or more.

FIG. 2B is a flowchart illustrating from a manufacturing of the surface emitting laser 100 to an alignment of an optical fiber to the surface emitting laser 100. In step S10, the surface emitting laser 100 is manufactured. In step S12, a chip of the surface emitting laser 100 is picked up by a collet and conveyed to a tray, and on the tray, an appearance inspection of the surface emitting laser 100 is performed. The surface emitting laser 100 which is judged good in the appearance inspection is picked up from the tray and mounted on a printed circuit board or the like (step S14). Thus, a module is fabricated. In step S16, an optical fiber is positionally aligned with respect to the surface emitting laser 100. Both in steps S14 and S16, an image of the pad 50 is used as a positional reference, and a position at which the surface emitting laser 100 be mounted and a position of the light emitting portion to which the optical fiber be aligned are determined.

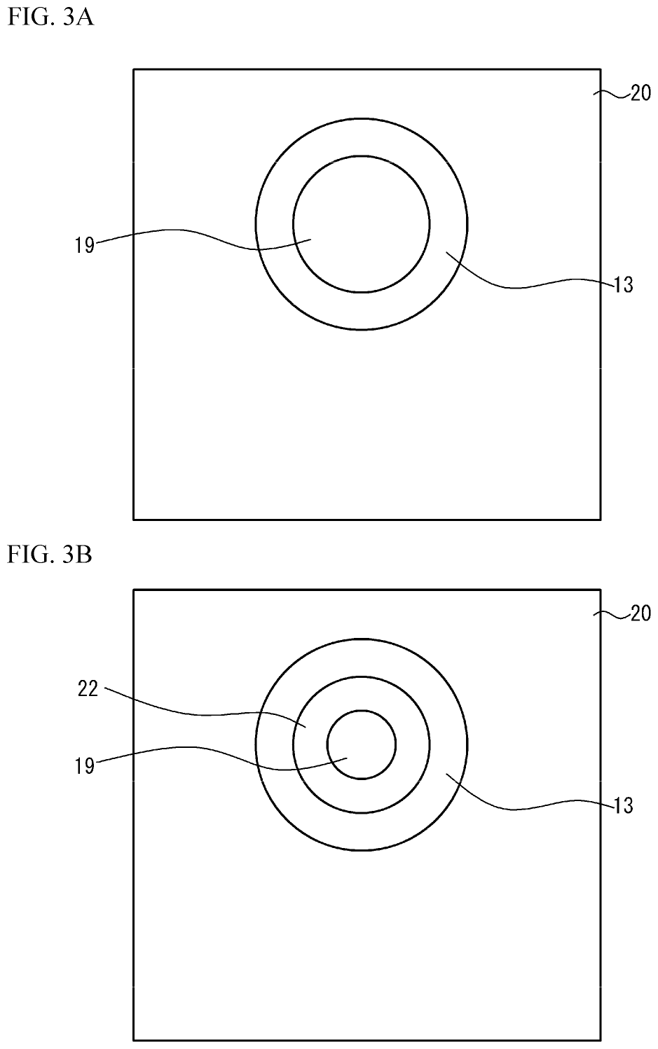

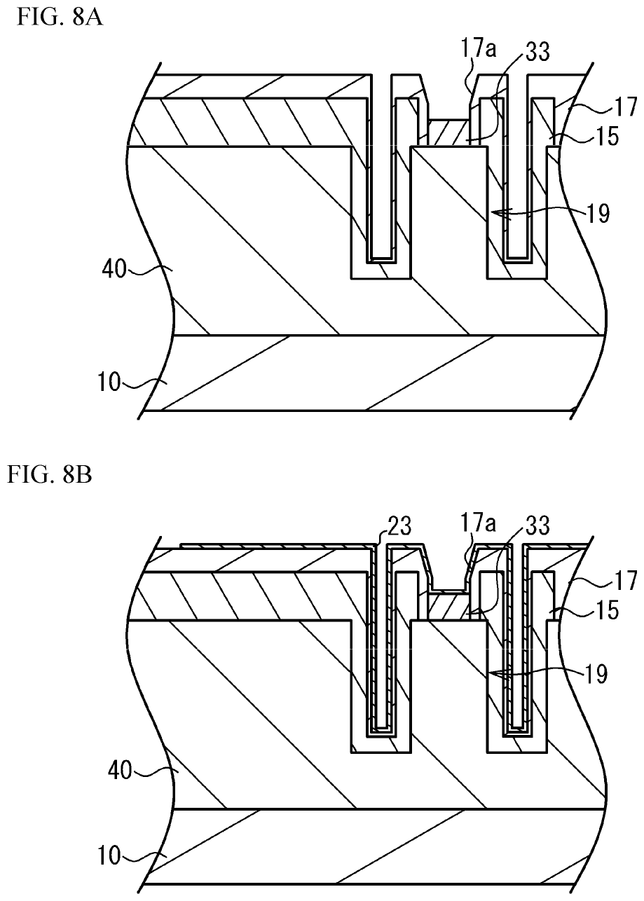

(Manufacturing Method) Next, a method of manufacturing the surface emitting laser 100 will be described. FIG. 3A to FIG. 7B are plan views illustrating the manufacturing methods of the surface emitting laser 100. FIG. 8A to FIG. 10B are cross-sectional views showing a forming of the pad 50. These steps are included in step S10 of the flowchart in FIG. 2B.

First, the lower reflector layer 12, the active layer 14, and the upper reflector layer 16 are epitaxially grown in this order on the substrate 10 by, for example, a metal-organic vapor phase epitaxy (MOVPE) method or a molecular beam epitaxy (MBE) method. The upper reflector layer 16 includes an AlₓGa₁₋ₓAs layer (0.9≤x≤1.0) for forming the current confinement layer 22.

As illustrated in FIG. 3A, the high-resistance region 20 is formed by ion implantation. Specifically, for example, a photoresist having a thickness of 10 μm or more and 15 μm or less is spin-coated on the semiconductor. A resist mask is formed from the photoresist by using a photolithography using ultraviolet (UV) light and an alkaline solution. For example, ions such as proton (H⁺) are implanted to form the high-resistance region 20. The proton is not implanted into a portion of the semiconductor layer masked with the photoresist, and the proton is implanted into a portion exposed from the photoresist. The implantation depth is, for example, 5 μm from a surface of the semiconductor layer. After the ion implantation, the resist mask is removed by an organic solvent and an ashing with an oxygen plasma.

As illustrated in FIG. 3A, the mesa 19 is formed by dry etching of the high-resistance region 20 by using, for example, inductively coupled plasma reactive ion etching (ICP-RIE). At this time, the groove 13 reaching the lower reflector layer 12 is formed in the high resistance region 20, and a portion which is not etched is protected by a photoresist (not illustrated). As an etching gas, for example, a BCl₃ gas or a mixed gas of BCl₃ and Cl₂ is used. Examples of etching conditions are shown below.
BCl₃/Ar=30 sccm/70 sccm
(or BCl₃/Cl₂/Ar=20 sccm/10 sccm/70 sccm)
ICP power: 50 W to 1000 W
Bias power: 50 W to 500 W
Temperature of the substrate: 25° C. or less

As illustrated in FIG. 3B, a portion of the upper reflector layer 16 of the mesa 19 is oxidized from the end portion of the mesa 19 by heating the upper reflector layer 16 to about 400° C. in a steam atmosphere, for example, to form the current confinement layer 22. The heating time is determined so that the current confinement layer 22 reaches a predetermined width and an unoxidized portion having a predetermined width remains inside the current confinement layer 22.

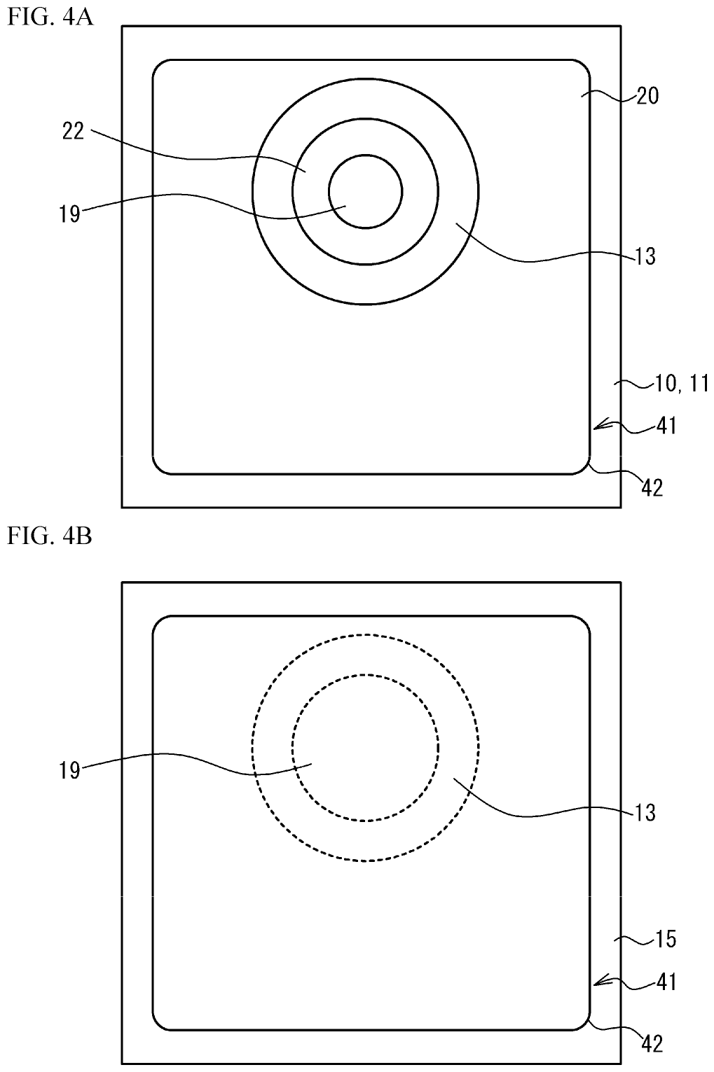

As illustrated in FIG. 4A, the trenches 11 are formed by dry-etching of the high-resistance region 20, the lower reflector layer 12, and the substrate 10. At this time, portions not etched such as the mesa 19 and the groove 13 are covered with a photoresist (not illustrated). As an etching gas, for example, a BCl₃ gas or a mixed gas of BCl₃ and Cl₂ is used. Examples of the etching conditions are shown below.
BCl₃/Ar=30 sccm/70 sccm
(or BCl₃/Cl₂/Ar=20 sccm/10 sccm/70 sccm)
ICP power: 50 W to 1000 W
Bias power: 50 W to 500 W
Temperature of the substrate: 25° C. or less

A depth of the trench 11 is, for example, 7 μm, and the substrate 10 is exposed in the trench 11. The mesa 41 having the chamfer 42 is formed inside the trench 11. Since the lower reflector layer 12, the active layer 14, and the upper reflector layer 16 are separated between the plurality of surface-emitting lasers 100, the plurality of surface-emitting lasers 100 are electrically separated. The distance between adjacent surface-emitting lasers 100 is, for example, 30 μm to 60 μm.

As illustrated in FIG. 4B, the insulating film 15 covering the wafer is formed by, for example, plasma-enhanced chemical vapor deposition (PECVD). The insulating film 15 is, for example, a SiON film or a SiO₂ film.

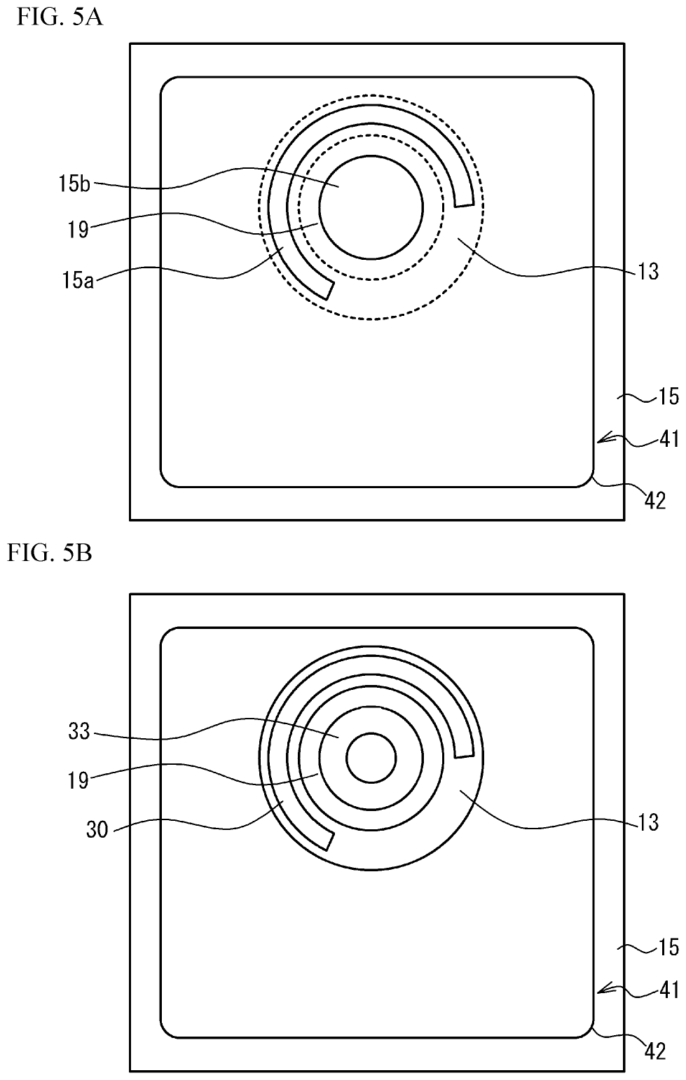

As illustrated in FIG. 5A, openings 15a and 15b are formed in the insulating film 15 by forming resist patterns, etching the insulating film 15 by using the resist patterns. The opening 15a is located in the groove 13 and the opening 15b is located on the mesa 19.

As illustrated in FIG. 5B, the electrode 30 is formed on a surface of the lower reflector layer 12 in the opening 15a by resist patterning and vacuum deposition method. The electrode 33 is formed on a surface of the upper reflector layer 16 in the opening 15b. After the electrodes 30 and 33 are formed, heat treatment is performed at a temperature of, e.g., about 400° C. for 1 minute, whereby ohmic contacts are made between the electrodes 30, 33 and the semiconductor layers. The electrode 30 is electrically connected to the lower part reflector layer 12 and the electrode 33 is electrically connected to the upper reflector layer 16.

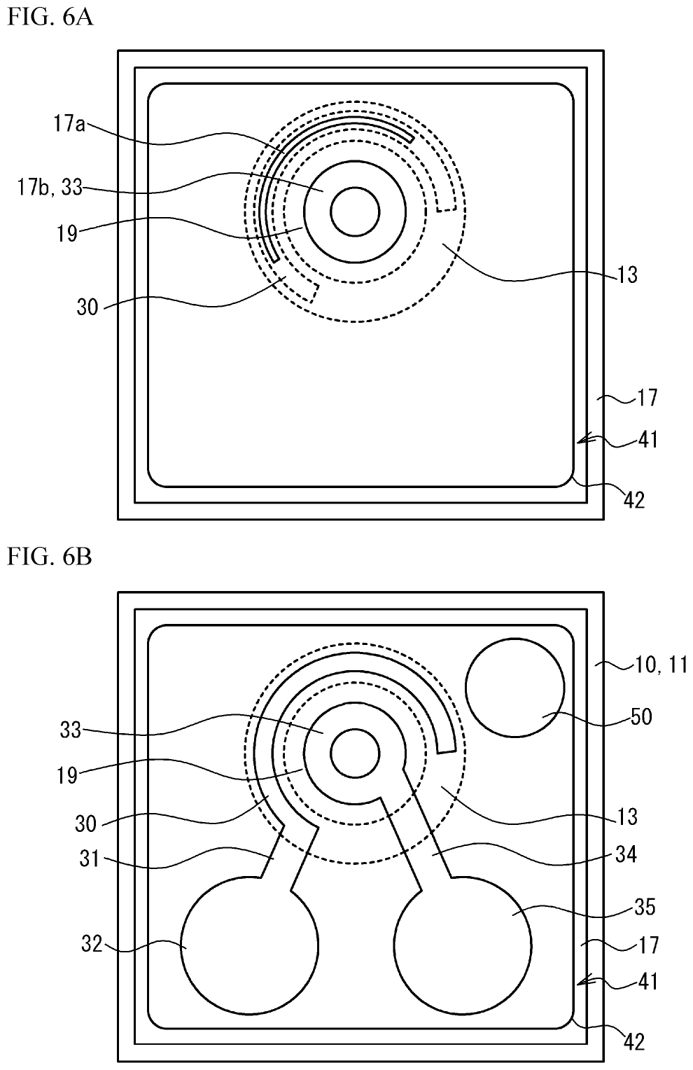

As illustrated in FIG. 6A, the insulating film 17 is formed on the insulating film 15, and on the electrodes 30 and 33 by, for example, PECVD. The insulating film 17 is formed of an insulator such as SiN, for example. As illustrated in FIG. 6A and FIG. 8A, the insulating film 17 is etched by using a resist pattern to form an opening 17a in which the electrode 30 is exposed. Simultaneously, the insulating film 17 is etched using the resist pattern to form an opening 17b in which the electrode 33 is exposed. The portions of the insulating films 15 and 17 in the trench 11 are etched to expose the substrate 10.

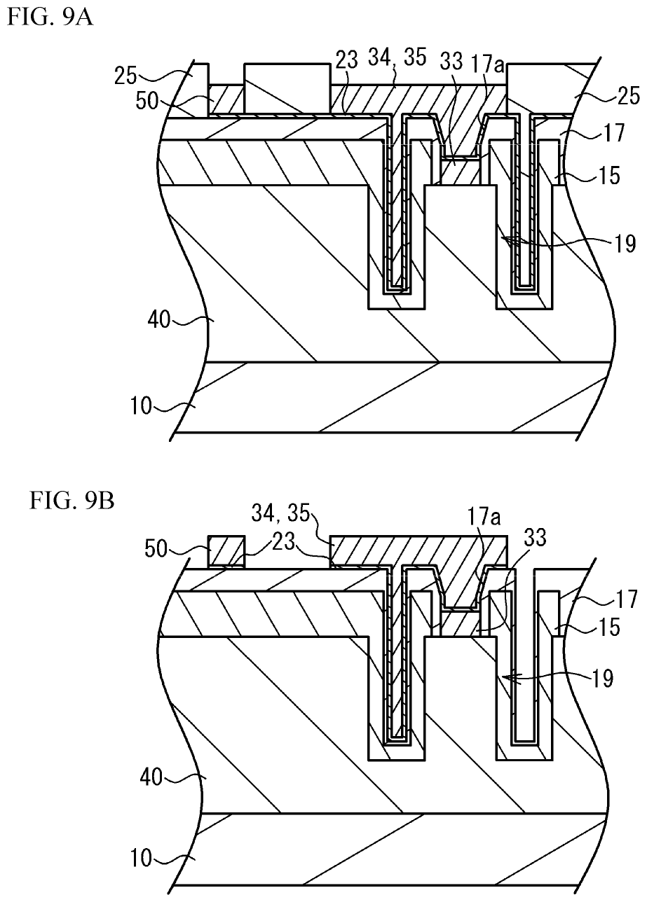

As illustrated in FIG. 6B, by a treatment including a metal plating, the wiring 31 and the pad 32 are formed so as to be connected to the electrode 30. The wiring 34 and the pad 35 are also formed so as to be connected to the electrode 33. Simultaneously, the pad 50 is formed in the treatment on the insulating film 17. More specifically, as illustrated in the FIG. 8B, the seed metal 23 is provided on the insulating film 17, the electrode 33, and the electrode 30 (not illustrated in FIG. 8B). As illustrated in FIG. 9A, a photoresist 25 is provided over the seed metal 23, and openings of the photoresist 25 are formed on areas where the wirings 31, 34 and the pads 32, 35, 50 are to be formed. The photoresist 25 is used in the metal plating process as a mask to form the wiring 31, 34, and the pads 32, 35, 50. As illustrated in FIG. 9B, the photoresist 25 is removed, and the seed metal 23 exposed from the wirings and the pads is removed by ion milling using argon ion (Ar⁺) or the like.

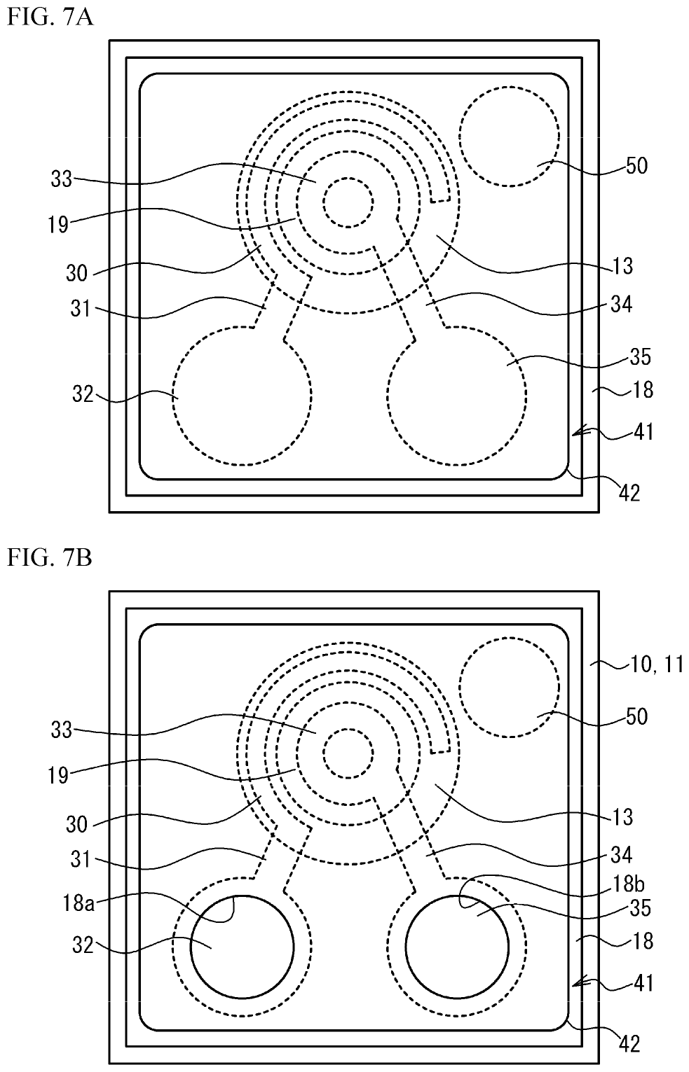

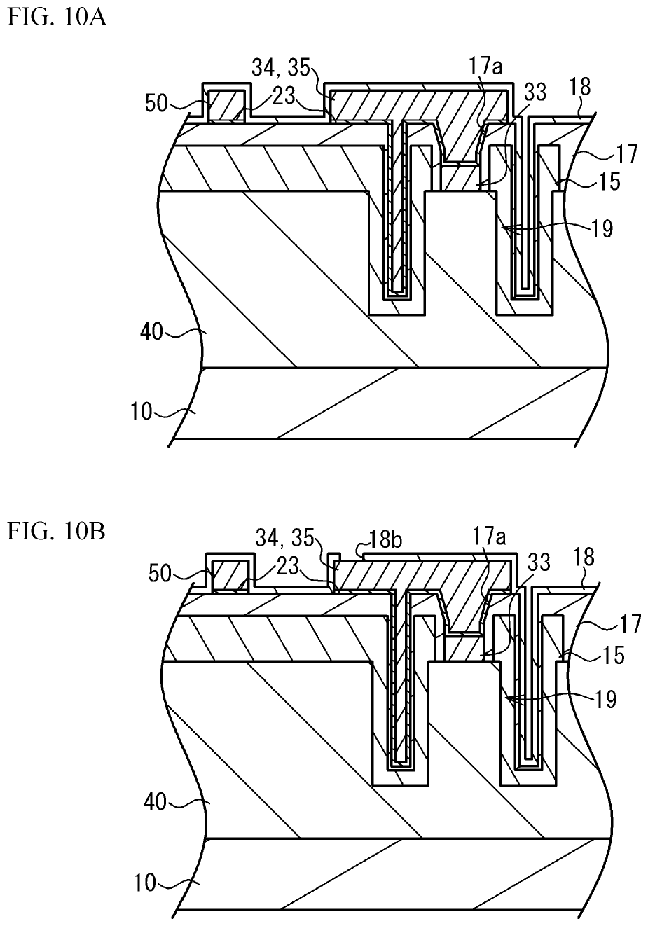

As illustrated in FIG. 7A and FIG. 10A, the insulating film 18 is formed by, for example, PECVD. The insulating film 18 is a passivation film formed of an insulator such as SiN, and covers the insulating film 17, the wirings 31, 34, and the pads 32, 35, 50.

As illustrated in FIG. 7B, a part of the insulating film 18 is etched to form the opening 18a through which the pad 32 is exposed and the opening 18b through which the pad 35 is exposed. The portion of the insulating film 18 in the trench 11 is also etched to expose the substrate 10 in the trench 11. As illustrated in FIG. 10B, the pad 50 is covered with the insulating film 18 and is not exposed from it. The pads 32 and 35 are used to be contacted by needle probes in a test for electrical properties. After the test, a back surface of the substrate 10 is polished by using a back grinder or a lapping machine to reduce a thickness of the substrate 10 to about 100 μm to 200 μm. The back surface of the substrate 10 is then bonded to a tape, and by using a blade or the like, the substrate 10 is cut along the trench 11 to form a plurality of the surface-emitting lasers 100.

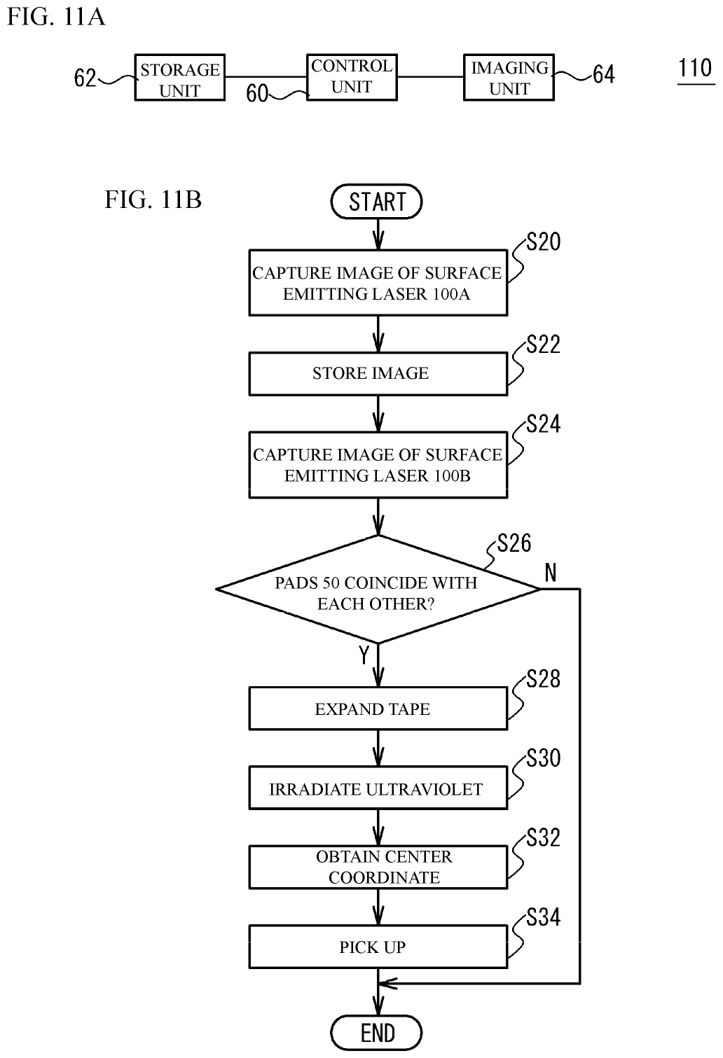

(Picking up of surface emitting laser 100) Each chip of the surface emitting laser 100 manufactured in the above-described process is picked up from the tape by using a collet, and then conveyed to a tray (step S12 in FIG. 2B). An image recognition of the surface emitting laser 100 is performed before the surface emitting laser 100 being picked up. FIG. 11A is a block diagram illustrating an image recognition apparatus 110. The image recognition apparatus 110 includes a control unit 60, a storage unit 62 and an imaging unit 64.

The control unit 60 includes an arithmetic unit such as a CPU (Central Processing Unit). The storage unit 62 is, for example, an HDD (hard disk drive) or an SSD (solid state drive), and the storage unit 62 preserves an image serving as a standard for the image recognition. The storage unit 62 preserves a coordinate value (X1, Y1) of a center C of the surface emitting laser 100 with reference to a center of the pad 50. The storage unit 62 also preserves a coordinate value (X2, Y2) of the mesa 19. The storage unit may preserve other coordinate values of other elements of the surface emitting laser 100. These coordinates can be calculated in advance from a designed dimension of the photoresist 25 illustrated in FIG. 9A, for example. The imaging unit 64 includes, for example, a microscope and a camera.

In the image recognition of the surface emitting laser 100, the image recognition apparatus 110 performs an image recognition of the pad 50. More specifically, an image of the surface emitting laser 100 is acquired by using the imaging unit 64, then a shape of the pad 50 in the acquired image is collated with a shape of the standard image of the pad 50 preserved in the storage unit 62. Thus, the image recognition apparatus 110 recognizes the pad 50 of the surface emitting laser 100. By using the image of the pad 50, the control unit 60 can calculate a position where the collet for picking up the surface emitting laser will be landed on with respect to the pad 50.

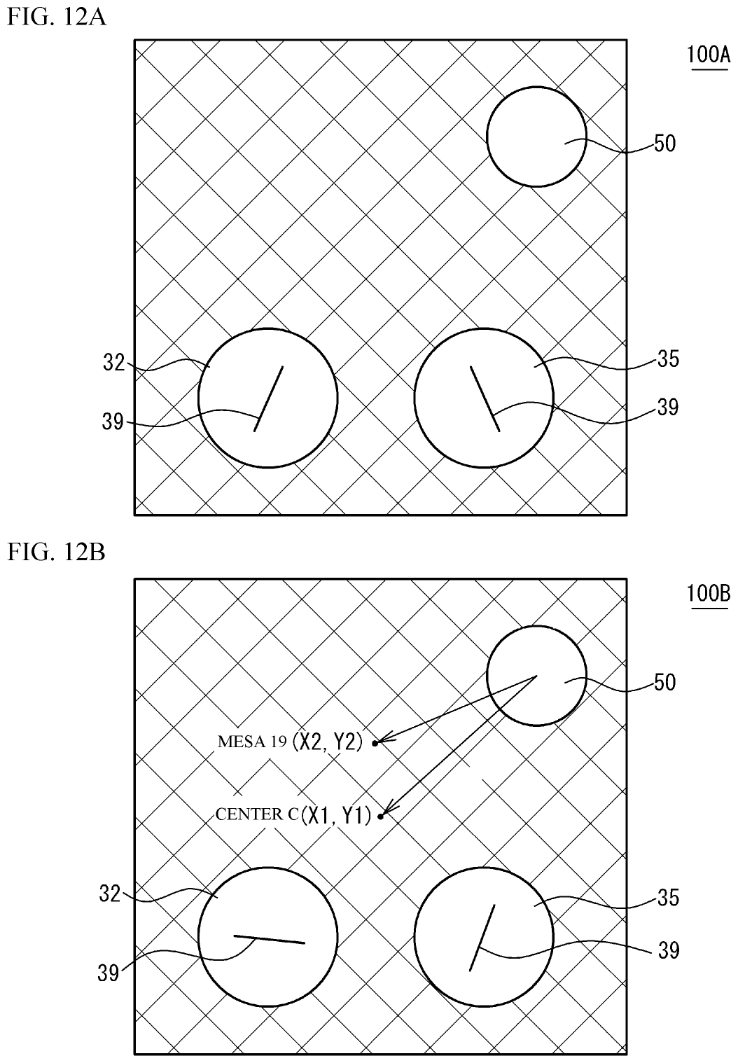

FIG. 11B is a flowchart illustrating a control executed by the image recognition apparatus 110. FIG. 12A and FIG. 12B are diagrams illustrating images of surface emitting lasers. Surface emitting lasers 100A and 100B are manufactured by the process described from FIG. 3A through FIG. 10B. A substrate including the surface emitting laser 100B is attached to the tape.

As illustrated in FIG. 11B, the imaging unit 64 captures an image of the surface emitting laser 100A which is a good sample (step S20). The image is binarized by the control unit 60, and the pads 32, 25, 50 become white areas as illustrated in FIG. 12A, and remaining area other than the pads are drawn in the image as a black area. In FIG. 12A and FIG. 12B, a hatched portion is the black area in the image. Since the probes are brought into contact with the pads 32 and 35 in the test for the electrical properties, traces 39 of the probes are marked on the pads 32 and 35. In the binarized image, the trace 39 is represented as a black line. On the other hand, the pad 50 which is a dummy pad is not used for the test and is not in contact with the probe, and thus is represented as a white circle without the trace 39 of the probe. In step S22, the storage unit 62 extracts the shape of the pad 50 from the captured image and stores the shape of the pad 50 as a standard. Steps S20 and S22 for the surface emitting laser 100A may be performed before manufacturing the surface emitting laser 100B.

As illustrated in FIG. 11B, the imaging unit 64, among a plurality of surface emitting laser 100 arranged on the tape, captures an image of the surface emitting laser 100B (step S24). By the control unit 60 binarizing the image, the pads 32, 25, 50 turn to white circles in the image as illustrated in FIG. 12B. The control unit 60 compares the images of the surface emitting laser 100A and the surface emitting laser 100B. The control unit 60 judges whether the shape of the pad 50 of the surface emitting laser 100B matches that of the surface emitting laser 100A (step S26). In a case where the judgement of the control unit 60 is negative (No), the control unit 60 does not recognize the pad 50 of the surface emitting laser 100B. An existence of the surface emitting laser 100B is not recognized. The control is ended and the surface emitting laser 100B is not picked-up from the tape.

In the case where the judgement is affirmative (Yes), the control unit 60 recognizes the image of the pad 50 of the surface emitting laser 100B, and recognizes an existence of the surface emitting laser 100B. Then, an expander is used to extend the tape in a planar direction so as to increase separations among the plurality of surface emitting lasers 100B (step S28). In step S30, a strength of adhesion of the tape is reduced by irradiating the tape with ultraviolet rays from a back surface of the tape.

The control unit 60 determines a coordinate value (X1, Y1) of the center C of the surface emitting laser 100 with reference to the center of the pad 50, based on the coordinate values stored in the storage unit 62 (step S32, FIG. 12B). The center C of the surface emitting laser 100B is pushed from the back surface with a needle or the like. Simultaneously, a collet sucks an upper surface of the surface emitting laser 100B in a vicinity of the center C. Then the surface emitting laser 100B is peeled off the tape and picked up (step S34). The collet conveys the surface emitting laser 100B to the tray. An appearance inspection of the surface emitting laser 100B is performed on the tray. Thus, the control ends.

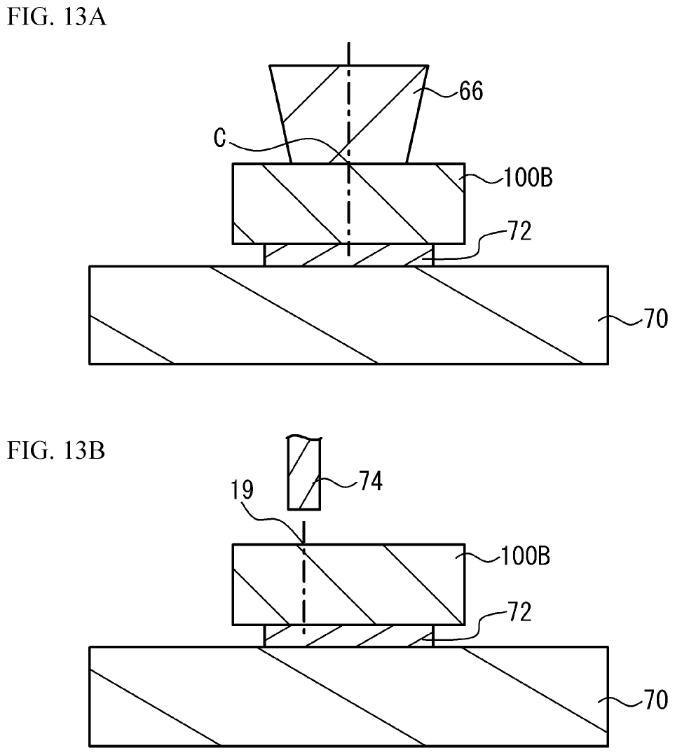

After the appearance inspection, the surface emitting laser 100 is proceeded to a mounting (step S14 in FIG. 2B). Also in the mounting, the image recognition apparatus 110 is used in order to determine a position of a circuit board 70 where the surface emitting laser 100B is to be mounted on, and the same control as steps S24, S26, S32, and S34 in FIG. 11B is performed. The storage unit 62 stores the coordinates of the surface-emitting laser 100B, which are regarded as non-defective in the appearance inspection. The control unit 60 recognizes the image of the pad 50 of the surface emitting laser 100B, and acquires the coordinates of the center C of the surface emitting laser 100B with reference to the pad 50. FIG. 13A is a cross-sectional view illustrating the mounting step. As illustrated in FIG. 13A, a collet 66 is moved to a vicinity of the center C of the surface emitting laser 100B on the tray, and picks it up by sucking in the vicinity of the center C. The collet 66 conveys the surface emitting laser 100B above the position of the circuit board 70. An adhesive 72 such as epoxy resin is provided in advance at the predetermined position of the circuit board 70. The surface emitting laser 100B is aligned so that the center C is above the adhesive 72. The surface emitting laser 100B is then put on the adhesive 72 and fixed on the circuit board 70 by curing the adhesive 72.

Next, an optical fiber 74 is aligned with respect to the surface emitting laser 100B mounted on the circuit board 70 (step S16 in FIG. 2B). FIG. 13B is a cross-sectional view illustrating an alignment of the optical fiber 74. The control unit 60 recognizes again the image of the pad 50 of the surface emitting laser 100B, determines a coordinate value (X2, Y2) of the mesa 19 of the surface emitting laser 100B with reference to the center of the pad 50, based on the coordinate values stored in the storage unit 62. As illustrated in FIG. 13B, the optical fiber 74 is positioned over the mesa 19, and fixed by using, for example, an adhesive (not illustrated).

As illustrated in FIG. 12A and FIG. 12B, the pads 32 and 35 are also white circles in the image, but are difficult to be used in the above-mentioned image recognition instead of the pad 50. Orientations and lengths of the traces 39 are not constant due to a variety of orientations and forces of the probes. For example, the orientations of the trace 39 is different between FIG. 12A and FIG. 12B. Therefore, if the pad 32 of the surface emitting laser 100A is adopted as a reference, the surface emitting laser 100B would not be picked up or mounded because the image of the pad 32 of the surface emitting laser 100B does not coincide with that of the surface emitting laser 100A owing to the traces 39 on the pads 32. The image recognition based on the pad 32 is difficult, in step S26 of FIG. 11B.

According to the first embodiment, the surface emitting laser 100 has the pads 32, 35 and 50. As illustrated in FIG. 12A and FIG. 12B, these pads are represented as white areas in the image. The pad 50 is not electrically connected to the other pads 32, 35 and the mesa 19. The pad 50 is not made contact with probes or the like in the test for the electrical properties. Therefore, the trace 39 is not formed on the pad 50. Therefore, by collating the images of the pads 50 of the surface emitting lasers 100A and 100B, the control unit 60 can recognize the existence of the surface emitting laser 100B. Further, the coordinate value of the center C and the coordinate of the mesa 19 with respect to the pad 50 are determined. As a result, in the pickup of the surface emitting laser 100B, in the mounting of the surface emitting laser 100B, and in the alignment of the optical fiber 74, accuracies of the position are improved.

As illustrated in FIG. 1A, the pads 32, 35 and 50 are circular and similar to each other. On the other hand, the diameter d2 of the pads 32 and 35 is larger than the diameter d1 of the pad 50. Therefore, the pad 50 can be distinguished from the pads 32, 35, and thus the image recognition can be performed. The pad 50 may have a shape similar to those of the pads 32, 35, and may have a difference in size.

The pads 32, 35 and 50 may be circular, or oval and polygonal, for example. The shape of the pad 50 is preferably a circular shape or a rectangular shape having two or more axes of symmetry. The coordinate values of the center of the pad 50 can be easily acquired, and the coordinate value of the center of the pad 50 can be used as a standard for calculating the other coordinates. In a case where the pad has the shape of polygon, and if apex of the polygonal pad be missing, it might become difficult to recognize a shape of the pad 50. Therefore, the shape of the pad 50 is particularly preferably circular. Note that an edge of the circular pad may not necessarily be a perfectly smooth curve, and may have roughness of, for example, about several microns. The shape of the pads may be, for example, symbols such as “+” and geometric patterns and geometric figures. Since the surface emitting laser 100 may be provided with identification codes including letters and numbers, the shape of the pad 50 is different from these codes.

The diameter d1 of the pad 50 is, for example, 40 μm or more and less than 60 μm, and the diameter d2 of the pads 32 and 35 is, for example, 60 μm or more. Since the diameter d1 is smaller than the diameter d2, the pad 50 can be distinguished from the pads 32 and 35. If the diameter d1 is too small, the circularity of the pad 50 decreases, and the image recognition becomes difficult. Therefore, the diameter dl is preferably 40 μm or more. The number of the pads 50 may be one or plural.

The insulating film 18 covers the pad 50 and has the openings 18a and 18b through which the pads 32 and 35 are exposed. The pads are formed of a metal such as Au. By the imaging unit 64 capturing an image, by the control unit 60 binarizing the image, the images in which the pads are represented as white circles as shown in FIG. 12A and FIG. 12B are obtained. Using these binarized images to recognize the surface emitting laser 100, it is possible to determine the coordinate values of the mesa 19 and of the center C of the surface emitting laser 100.

Although the embodiments of the present disclosure have been described above in detail, the present disclosure is not limited to the specific embodiments, and various modifications and variations are possible within the scope of the gist of the present disclosure described in the claims.

What is claimed is:

1. A vertical cavity surface-emitting laser comprising:
a light emitting portion provided on a substrate;
a first pad provided on the substrate, the first pad being electrically connected to the light emitting portion; and
a second pad provided on the substrate, the second pad being electrically isolated from the light emitting portion and the first pad.

2. The vertical cavity surface-emitting laser according to claim 1, wherein
the second pad has a shape which is similar to that of the first pad, and
the second pad has a size different from that of the first pad.

3. The vertical cavity surface-emitting laser according to claim 1, wherein the first pat and the second pad have circular shapes.

4. The vertical cavity surface-emitting laser according to claim 3, wherein
the first pad has a diameter of 60 μm or more, and
the second pad has a diameter of 40 μm or more and less than 60 μm.

5. The vertical cavity surface-emitting laser according to claim 1, further comprising
an insulating film covering the second pad, the insulating film having a first opening through which the first pad is exposed.

6. The vertical cavity surface-emitting laser according to claim 1, wherein the first pad and the second pad are formed of gold.

7. A method of manufacturing a vertical cavity surface-emitting laser comprising steps of:
forming a light emitting portion on a substrate;
forming a first pad on the substrate, the first pad being electrically connected to the light emitting portion; and
forming a second pad on the substrate, the second pad being electrically isolated from the light emitting portion and the first pad.

8. A method of manufacturing a module comprising steps of:
preparing a vertical cavity surface-emitting laser having a light emitting portion provided on a substrate, a first pad provided on the substrate, and a second pad provided on the substrate, the first pad being electrically connected to the light emitting portion, the second pad being electrically isolated from the light emitting portion and the first pad;
detecting a position of the vertical cavity surface-emitting laser by capturing an image of the second pad;
mounting the vertical cavity surface-emitting laser on another substrate by using the position detected in the detecting.

9. The method according to claim 8, further comprising
positionally aligning an optical fiber with respect to the vertical cavity surface-emitting laser by using the position detected in the detecting.

10. A method of picking up a vertical cavity surface-emitting laser comprising steps of:
storing an image of a first vertical cavity surface-emitting laser having a light emitting portion provided on a substrate, a first pad provided on the substrate, and a second pad provided on the substrate, the first pad being electrically connected to the light emitting portion, the second pad being electrically isolated from the light emitting portion and the first pad;
capturing an image of a second vertical cavity surface-emitting laser having a light emitting portion provided on a substrate, a first pad provided on the substrate, and a second pad provided on the substrate, the first pad being electrically connected to the light emitting portion, the second pad being electrically isolated from the light emitting portion and the first pad;
determining whether to pick up the second vertical cavity surface-emitting laser, based on a collation results between the second pad in the image of the first vertical cavity surface-emitting laser and the second pad in the image of the second vertical cavity surface-emitting laser.

11. The method according to claim 10, wherein the first image and the second image are binarized images.
